(19) United States
(12) Patent Application Publication
(10) Pub. No.: US 2022/0352051 A1
(43) Pub. Date: Nov. 3, 2022

(54) HEAT DISSIPATION MEMBER AND COOLING DEVICE

(71) Applicant: Nidec Corporation, Kyoto (JP)

(72) Inventors: Tsungting HSIEH, Taipei City (TW); Kwun-Yao HO, Taipei City (TW)

(21) Appl. No.: 17/715,086

(22) Filed: Apr. 7, 2022

Related U.S. Application Data
(60) Provisional application No. 63/180,890, filed on Apr. 28, 2021.

(30) Foreign Application Priority Data
Sep. 29, 2021 (JP) 2021-159851

(51) Int. Cl. H01L 23/473

(52) U.S. Cl. CPC H01L 23/473; H01L 25/18

(57) ABSTRACT

A heat dissipator includes a metal plate including a first surface through which fluid flows, first protrusions on the first surface, a recess in the first surface and between the first protrusions, and a second surface in contact with a heating element on an opposite side of the first surface.

### CROSS-REFERENCE TO RELATED APPLICATIONS

The present application is a non-provisional application of U.S. provisional Patent Application No. 63/180,890, filed on Apr. 28, 2021, with priority under 35 U.S.C. § 119(a) being claimed from Japanese Patent Application No. 2021-159851, filed on Sep. 29, 2021, the entire disclosures of which are hereby incorporated herein by reference.

### 1. FIELD OF THE INVENTION

The present disclosure relates to a heat dissipator and a cooling device including the heat dissipator.

### 2. BACKGROUND

As a cooling device for cooling an electronic component (for example, a semiconductor module such as an IGBT), a cooling device including a heat dissipator having a plurality of pins (cooling fins) has been known.

However, when the electronic component with high power consumption is cooled, there is a probability that sufficient cooling is not performed with heat dissipation capability of the conventional pin-type cooling fins. Further, in the case of the heat dissipator including the pin-type cooling fins, when the number of pin-type cooling fins is large, large fluid resistance is generated with respect to a refrigerant flowing between the pin-type cooling fins. When the fluid resistance to the refrigerant is large, a load on a pump that supplies the refrigerant to the cooling device increases.

### SUMMARY

A heat dissipator according to an example embodiment of the present disclosure includes a metal plate including a first surface through which fluid flows, first protrusions on the first surface, a recess in the first surface and between the first protrusions, and a second surface in contact with a heating element on an opposite side of the first surface.

Heat generated by the heating element is transferred from the second surface side to the first surface side of the metal plate. Then, the heat is dissipated to the fluid via the first surface of the metal plate, the first protrusions, and the recess. Since a heat dissipation area on the first surface side is increased because of the first protrusions and the recess provided on the first surface, heat dissipation capability of the heat dissipator is increased. The above increase in the heat dissipation capability is achieved not by increasing the number of first protrusions but by providing the recess, so that an increase in the fluid resistance is reduced or prevented. In addition, since the recess is adjacent to the heating element (on a second surface) as a heat source, a distance (heat transfer distance) between the heat source and a heat dissipation portion is shortened. When the heat transfer distance is short, the heat dissipation capability (heat dissipation efficiency) of the heat dissipator is increased.

Each of the first protrusions may be a pillar-shaped body having a polygonal, circular, or elliptical cross section. That is, when the first protrusion is the pillar-shaped body, the pillar-shaped body may be a triangular prism, a quadrangular prism, or the like, or may be a cylinder or an elliptic cylinder. Since the heat dissipation area of the heat dissipator is increased because of the pillar-shaped body, the heat dissipation capability of the heat dissipator is improved.

A shape of the cross section of the pillar-shaped body may be unvaried in a direction perpendicular to the first surface. That is, the cross section of the pillar-shaped body may be constant from a base portion toward a tip. Alternatively, an area of the cross section of the pillar-shaped body may be varied in the direction perpendicular to the first surface. That is, the cross section of the pillar-shaped body may be varied from the base portion toward the tip (for example, a tapered-shape).

The recess includes, for example, at least one groove. Since the heat dissipation area on the first surface side is increased because of the groove, the heat dissipation capability of the heat dissipator is increased.

The recess may include at least one of the groove extending in a direction in which the fluid flows and the groove extending in a direction intersecting with the direction in which the fluid flows. That is, a longitudinal direction of the groove may be the same as or may intersect with the direction in which the fluid flows.

The recess may include a plurality of the grooves extending parallel to each other. That is, the grooves may be parallel to each other. Alternatively, the recess may include a plurality of the grooves extending non-parallel to each other. That is, the grooves may not be parallel to each other.

Each of the at least one groove may have a semicircular, semi-elliptical or polygonal cross-sectional shape. That is, the cross section of each of the groove may be a semicircle, a semi ellipse, a triangle, a quadrangle, or the like.

The cross-sectional shape of each of the at least one groove may be asymmetric.

When the cross-sectional shape of the groove is the polygon, a corner of the polygon may be a smooth curved surface.

The recess may include a plurality of the grooves, and a second protrusion may be provided between adjacent grooves among the plurality of grooves. By providing the second protrusion between the grooves, the heat dissipation area is further increased, so that the heat dissipation capability is further improved. A height of the second protrusion is lower than a height of the first protrusion. Since the second protrusion is a protrusion lower than the first protrusion, the increase in the fluid resistance due to the second protrusion is suppressed.

When the first protrusions are arranged perpendicularly to the direction in which the fluid flows, the recess may be provided upstream of the plurality of first protrusions. When the recess is positioned upstream of the first protrusions, the heat dissipation capability of the first protrusion is improved because of a vortex generated in the recess.

A cooling device according to a second example embodiment of the present disclosure includes the heat dissipator described above, and a housing that accommodates at least the first protrusions of the heat dissipator and allows the fluid to flow through a gap between the first protrusions, with the housing including an inlet and an outlet for the fluid.

Since the cooling device includes the heat dissipator described above, the heat (the heat generated by the heating element) transferred from the second surface side of the metal plate is dissipated to the fluid via the first surface of the metal plate, the first protrusion, and the recess. Since the heat dissipation area on the first surface side is increased because of the first protrusions and the recess provided on the first surface, the heat dissipation capability of the heat dissipator is increased. The above increase in the heat dissipation capability is achieved not by increasing the number of first protrusions but by providing the recess, so that increase in the fluid resistance is reduced or prevented. In addition, since the recess is close to the heating element (second surface) as a heat source, a distance (heat transfer distance) between the heat source and a heat dissipation portion is shortened. When the heat transfer distance is short, the heat dissipation capability (heat dissipation efficiency) of the heat dissipator increases, so that cooling capability of the cooling device is also improved.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1A is a schematic perspective view of a cooling device according to a first example embodiment of the present disclosure.

FIG. 1B is a side view of a heat dissipator of the cooling device illustrated in FIG. 1A.

FIG. 2A is a view illustrating a portion of a lower surface of a plate material before grooves are formed, and FIG. 2B is a cross-sectional view taken along line 2B-2B in FIG. 2A.

FIG. 3A is a view illustrating a portion of the lower surface of the plate material after the grooves are formed, and FIG. 3B is a cross-sectional view taken along line 3B-3B in FIG. 3A.

FIG. 4A is a view illustrating a portion of a lower surface of a heat dissipator according to a second example embodiment of the present disclosure, and FIG. 4B is a cross-sectional view taken along line 4B-4B in FIG. 4A.

FIG. 5A is a view illustrating a portion of a lower surface of a heat dissipator according to a third example embodiment of the present disclosure, and FIG. 5B is a cross-sectional view taken along line 5B-5B in FIG. 5A.

FIG. 6A is a view illustrating a portion of a lower surface of a heat dissipator according to a fourth example embodiment of the present disclosure, and FIG. 6B is a cross-sectional view taken along line 6B-6B in FIG. 6A.

FIG. 7A is a view illustrating a portion of a lower surface of a heat dissipator according to a fifth example embodiment of the present disclosure, and FIG. 7B is a cross-sectional view taken along line 7B-7B in FIG. 7A.

FIG. 8A is a view illustrating a portion of a lower surface of a heat dissipator according to a sixth example embodiment of the present disclosure, FIG. 8B is a cross-sectional view taken along line 8B-8B in FIG. 8A, FIG. 8C is a bottom view of a small projection, and FIG. 8D is a perspective view of the small projection.

FIG. 9A is a bottom view of a heat dissipator according to a seventh example embodiment of the present disclosure, FIG. 9B is a cross-sectional view taken along line 9B-9B in FIG. 9A, and FIG. 9C is a partially enlarged view of FIG. 9B.

FIG. 10A is a bottom view of a heat dissipator according to an eighth example embodiment of the present disclosure, FIG. 10B is a cross-sectional view taken along line 10B-10B in FIG. 10A, and FIG. 10C is a partially enlarged view of FIG. 10B.

### DETAILED DESCRIPTION

Heat dissipators and cooling devices according to example embodiments of the present disclosure will be described hereinafter with reference to the drawings. It is to be noted that the scope of the present disclosure is not limited to the following example embodiments and may be changed as appropriate within the technical idea of the present disclosure. Further, in the following drawings, in order to easily understand each component, a scale, the number, and so on, of each structure may be different from those of actual structures.

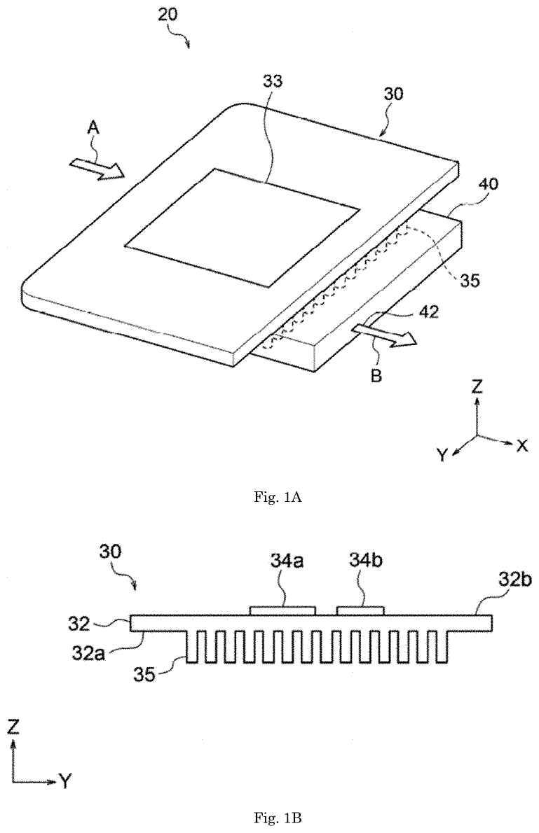

In the drawings, an XYZ coordinate system is illustrated appropriately as a three-dimensional orthogonal coordinate system. In the XYZ coordinate system, a Z-axis direction is a vertical direction, and is a height direction of a cooling device 20 in FIG. 1A. An X-axis direction is a direction orthogonal to the Z-axis direction. The X-axis direction is a width direction (left and right direction) of the cooling device 20 in FIG. 1A. A Y-axis direction is assumed to be a direction orthogonal to both the X-axis direction and the Z-axis direction.

In the following description, the height direction (Z-axis direction) of the cooling device 20 is defined as the vertical direction. A positive side (+Z side) in the Z-axis direction with respect to a certain object may be referred to as an “upper side”, and a negative side (−Z side) in the Z-axis direction with respect to a certain object may be referred to as a “lower side”. It is to be noted that the terms of the vertical direction, the upper side, and the lower side are made simply for the sake of convenience in description, and are not meant to restrict actual positional relationships or directions. In the present example embodiments, a case where the −Z side is seen from the upper side (+Z side) in the Z-axis direction is expressed as a case where the cooling device 20 is seen in plan view.

A first example embodiment of the present disclosure will be described with reference to FIGS. 1A to 3B. FIG. 1A is a schematic perspective view of a cooling device 20 according to the first example embodiment. FIG. 1B is a side view of a heat dissipator 30 of the cooling device 20 as seen in an −X-axis direction.

As illustrated in FIG. 1A, the cooling device 20 includes the heat dissipator 30 and a housing 40 that accommodates a part of the heat dissipator 30. Cooling fluid (refrigerant) flows into the cooling device 20 as indicated by an arrow A. The cooling fluid flowing in the cooling device 20 flows out of the cooling device 20 as indicated by an arrow B. The housing 40 has an inlet (not illustrated) and an outlet 42 for the cooling fluid. Reference numeral 33 denotes an electronic component arrangement region. The cooling fluid is, for example, water.

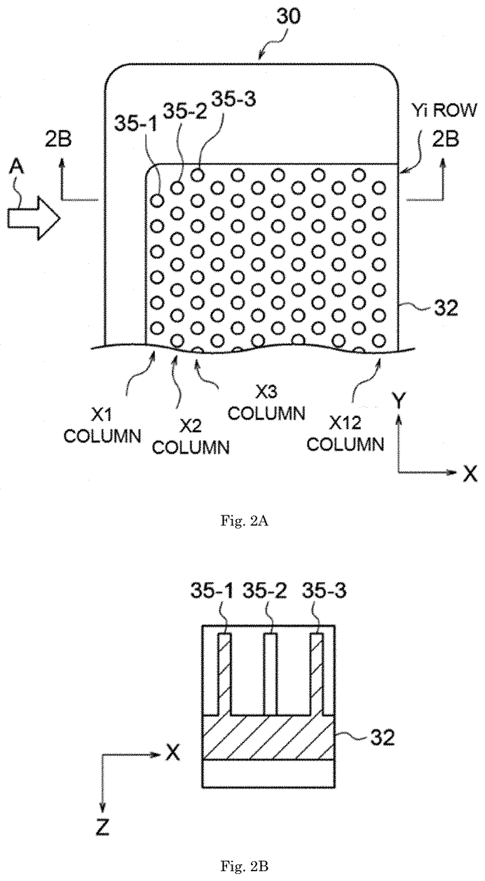

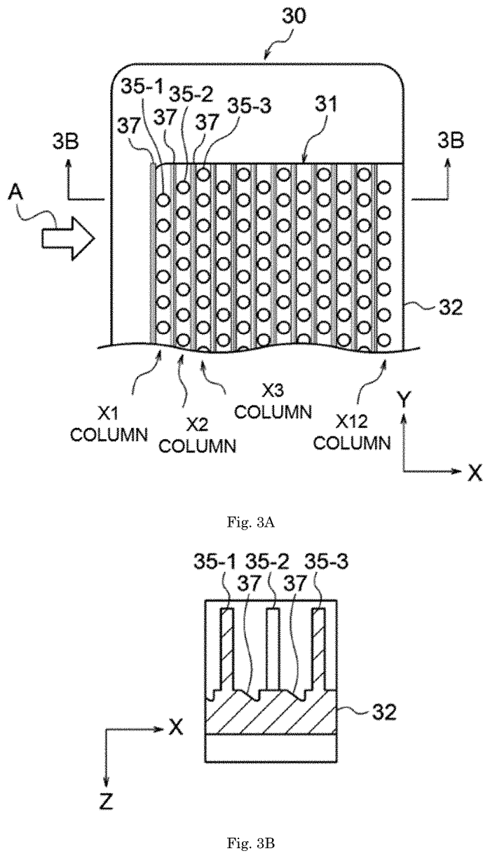

The heat dissipator 30 has a plate material 32 and a plurality of pillar-shaped bodies 35 extending vertically (−Z side in the Z-axis direction) from a lower surface 32a of the plate material 32. A shape and arrangement of each of the pillar-shaped bodies 35 will be described later with reference to FIGS. 2A to 3B. The pillar-shaped body 35 may be referred to as a first protrusion. The lower surface 32a may be referred to as a first surface of the plate material 32.

The plate material 32 is, for example, a metal plate such as a copper plate. The pillar-shaped bodies 35 are integrated with the plate material 32 and are made of copper. The heat dissipator 30 is formed by forging.

An upper surface 32b of the plate material 32 is a surface opposite to the lower surface 32a, and has the electronic component arrangement region 33 at the center thereof. The upper surface 32b may be referred to as a second surface of the plate material 32. As illustrated in FIG. 1B, electronic components such as an IGBT 34a and a diode 34b are provided in the electronic component arrangement region 33. The electronic components such as the IGBT 34a and the diode 34b are fixed to the plate material 32 by, for example, solder. The electronic components such as the IGBT 34a and the diode 34b generate heat when used, and thus may be referred to as heating elements. The IGBT is an abbreviation for Insulated Gate Bipolar Transistor.

Although, in FIG. 1B, the IGBT 34a and the diode 34b are drawn to be directly attached to the upper surface 32b of the plate material 32, a thermal sheet or the like may be provided between each of the IGBT 34a and the diode 34b, and the upper surface 32b, or a copper film, a ceramic film, or the like may be provided. That is, in the description of the upper surface 32b in the present specification, the expression that the upper surface 32b is in contact with the heating elements (IGBT 34a, diode 34b, and so on) on the opposite side of the lower surface 32a includes not only the upper surface 32b that is in direct contact with the heating elements but also the upper surface that is in indirect contact with the heating elements.

In FIG. 1A, the IGBT 34a and the diode 34b are omitted. Additionally, in FIG. 1A, the pillar-shaped bodies 35 of the heat dissipator 30 are accommodated in the housing 40, so that each of the pillar-shaped bodies 35 is drawn by a broken line.

The cooling device 20 of the present example embodiment is a device for cooling the electronic components as the heating elements when the electronic components such as the IGBT 34a and the diode 34b are used and generate heat. When the IGBT 34a, the diode 34b, and the like provided on the upper surface 32b of the plate material 32 generate heat, the heat is transferred from the upper surface 32b side to the lower surface 32a of the plate material 32, and is dissipated to the cooling fluid from the lower surface 32a side. The cooling fluid receiving the heat flows from the outlet 42 of the housing 40 to the outside.

FIG. 2A is a view illustrating a part of the lower surface 32a of the plate material 32, and FIG. 2B is a cross-sectional view taken along line 2B-2B in FIG. 2A, illustrating the pillar-shaped bodies 35 stood on the lower surface 32a. In the present example embodiment, each of the pillar-shaped bodies 35 is a column. A shape of a cross section of the pillar-shaped body 35 is unvaried in the Z-axis direction.

As illustrated in FIG. 2A, a large number of pillar-shaped bodies 35 are provided at predetermined intervals in the X-axis direction and the Y-axis direction. When viewed from a direction (direction of the arrow A) in which the cooling fluid flows, initially, there are a plurality of pillar-shaped bodies 35-1 provided side by side in an X1th column, and there are a plurality of pillar-shaped bodies 35-2 provided side by side in an X2th column behind (downstream side) the X1th column. Then, there are a plurality of pillar-shaped bodies 35-3 provided side by side in an X3th column behind (downstream side) the X2th column. In the present example embodiment, X columns of the pillar-shaped bodies 35 are from an X1 column to an X12 column.

When viewed from the direction of the arrow A, each of the pillar-shaped bodies 35-2 is positioned between the pillar-shaped bodies 35-1 adjacent each other, and each of the pillar-shaped bodies 35-3 is superimposed on the pillar-shaped body 35-1. It is to be noted that, in Y rows each of which is orthogonal to the X column, the pillar-shaped bodies 35 are arranged in a Y1 row to a Yi row (the uppermost row in FIG. 2A is the Yi row). In the present example embodiment, intervals between the X columns are equal, and intervals between the Y rows are also equal.

In FIG. 2B, the plate material 32, the pillar-shaped body 35-1 in the X1th column, the pillar-shaped body 35-2 in the X2th column, and the pillar-shaped body 35-3 in the X3th column are illustrated.

In the present example embodiment, grooves 37 illustrated in FIGS. 3A and 3B are formed on the lower surface 32a of the plate material 32 in a state illustrated in FIGS. 2A and 2B. Each of the grooves 37 is a recess formed in the plate material 32, and has a right triangular cross-sectional shape in the present example embodiment. Since the cross-sectional shape of the groove 37 is the right triangle, the cross-sectional shape is asymmetric. Corners of the right triangle may have smooth curved shapes. A rectangular heat dissipation region (heat dissipation portion) 31 is formed of the lower surface 32a of the plate material 32, the plurality of pillar-shaped bodies 35, and the grooves 37.

In the present example embodiment, twelve grooves 37 are formed. The twelve grooves 37 are parallel to each other. Each of the grooves 37 extends in the Y-axis direction. The number of grooves 37 is the same as the number of X columns (12) of the pillar-shaped bodies 35, and one groove 37 is positioned at an upstream side of the pillar-shaped bodies 35 of one X column. As seen from FIG. 3A, it is said that each of the grooves 37 is positioned between the pillar-shaped bodies 35.

The grooves 37 formed on the lower surface 32a of the plate material 32 increase a surface area of the lower surface 32a of the plate material 32, so that heat dissipation capability of the heat dissipator 30 is improved. When the cooling fluid flowing from the direction of the arrow A to the lower surface 32a of the plate material 32 flows into the groove 37, a vortex flow is generated by the groove 37. Since the groove 37 is provided upstream of the column of the pillar-shaped bodies 35, the heat dissipation capability (heat exchange capability) from the lower surface 32a of the plate material 32 and the heat dissipation capability of the pillar-shaped bodies 35 are improved by the vortex flow.

As described above, according to the present example embodiment, in the case of cooling the electronic components 34a, 34b that generate heat, the heat dissipation capability larger than that of conventional pin-type cooling fins is exhibited. In the present example embodiment, in order to improve the heat dissipation capability, the grooves 37 are formed on the plate material 32 instead of increasing the number of pillar-shaped bodies (pins) 35, so that large fluid resistance is not generated with respect to the cooling fluid (refrigerant). Since the fluid resistance to the cooling fluid is not large, load on a pump that supplies the cooling fluid to the cooling device 20 does not increase. Since the fluid resistance is not large, difference between pressure at the inlet of the cooling device and pressure at the outlet 42 is reduced.

It is to be noted that the present disclosure is not limited to the above described example embodiment. For example, the following configurations may be adopted.

(1)The number of X columns of the pillar-shaped bodies 35 is not limited to 12.

(2)The intervals between the X columns of the pillar-shaped bodies 35 may not be equal. Additionally, the intervals between the Y rows of the pillar-shaped bodies 35 may not be equal.

(3)The cross section of the pillar-shaped body 35 is not limited to a circle, and may be, for example, a polygon (a triangle, a quadrangle, or the like) or an ellipse.

(4)An area of the cross section of the pillar-shaped body 35 may be varied in the Z-axis direction. For example, the cross section of the pillar-shaped body 35 may be varied in a tapered-shape from a base portion (lower surface 32a) toward a tip.

(5)Although, in FIG. 3A, each of the grooves 37 extends in a direction (Y-axis direction) intersecting a direction (X-axis direction) in which the cooling fluid flows, each of the grooves 37 may extend in the X-axis direction.

(6)Although, in FIG. 3A, the grooves 37 are parallel to each other, the grooves 37 may be non-parallel.

(7)Although, in FIG. 3B, the cross section of the groove 37 is the triangle, the cross section may be a semicircle, a semi-ellipse, or a polygon. In the case of the polygon, corners may be smooth curved surfaces.

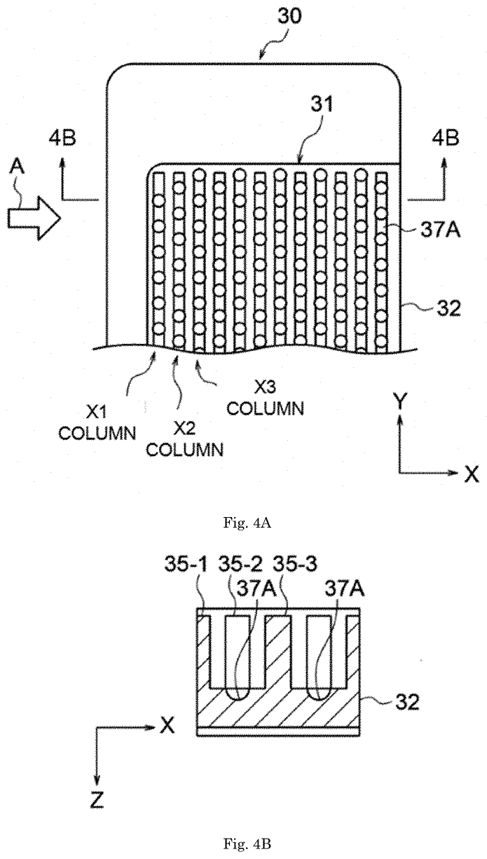

A second example embodiment of the present disclosure will be described with reference to FIGS. 4A and 4B. It is to be noted that description of configurations common to the first example embodiment will be omitted as appropriate. The same reference numerals are given to the same configurations as those of the first example embodiment. In the following description, differences from the first example embodiment will be mainly described.

FIG. 4A is a diagram corresponding to FIG. 3A, and FIG. 4B is a diagram corresponding to FIG. 3B. As illustrated in FIG. 4A, according to the second example embodiment, grooves 37A are formed in the X columns of the pillar-shaped bodies 35. That is, no groove is formed between the X columns of the pillar-shaped bodies 35 (for example, between the X1th column and the X2th column).

As seen from FIG. 4A, for example, when viewing the X1 column, the grooves 37A are formed between the pillar-shaped bodies 35 arranged at predetermined intervals in the Y-axis direction. As illustrated in FIG. 4B, a cross section of the groove 37A of the present example embodiment is a semicircle.

Also according to the present example embodiment, since the surface area of the lower surface 32a of the plate material 32 is increased by the grooves 37A, the heat dissipation capability of the heat dissipator 30 is improved. When the cooling fluid flowing from the direction of the arrow A to the lower surface 32a of the plate material 32 flows into the groove 37A, the vortex flow is generated by the groove 37A, and the heat dissipation capability from the lower surface 32a of the plate material 32 and the heat dissipation capability of the pillar-shaped bodies 35 are improved by the vortex flow. Also according to the present example embodiment, the number of pillar-shaped bodies (pins) 35 is not increased from the state of FIG. 2A, so that the large fluid resistance is not generated with respect to the cooling fluid (refrigerant).

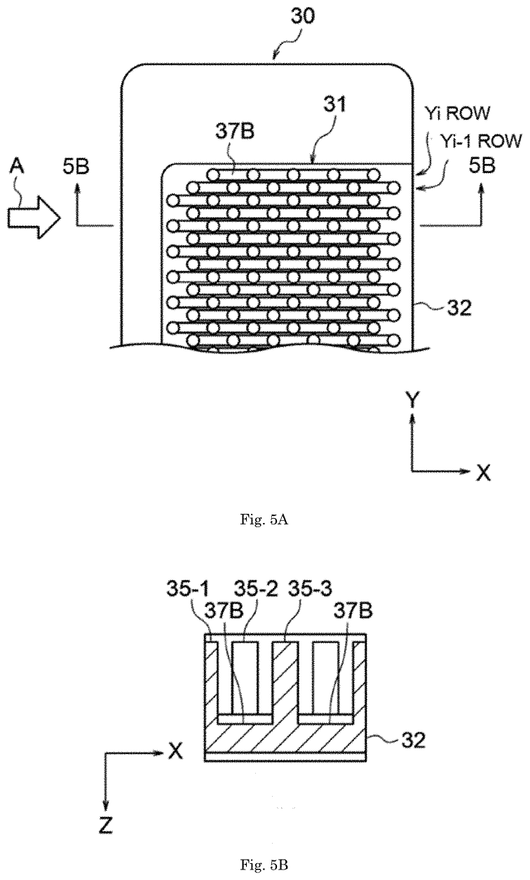

A third example embodiment of the present disclosure will be described with reference to FIGS. 5A and 5B. It is to be noted that description of configurations common to the second example embodiment will be omitted as appropriate. The same reference numerals are given to the same configurations as those of the second example embodiment. In the following description, differences from the second example embodiment will be mainly described.

FIG. 5A is a diagram corresponding to FIG. 4A, and FIG. 5B is a diagram corresponding to FIG. 4B. As illustrated in FIG. 5A, according to the third example embodiment, grooves 37B are formed in the Y rows of the pillar-shaped bodies 35.

As seen from FIG. 5A, for example, when viewing the Yi row, the grooves 37B are formed between the pillar-shaped bodies 35 arranged at predetermined intervals in the X-axis direction. As illustrated in FIG. 5B, a cross section of the groove 37B of the present example embodiment is a rectangle.

Also according to the present example embodiment, since the surface area of the lower surface 32a of the plate material 32 is increased by the grooves 37B, the heat dissipation capability of the heat dissipator 30 is improved. When the cooling fluid flowing from the direction of the arrow A to the lower surface 32a of the plate material 32 flows into the groove 37B, the vortex flow is generated by the groove 37B, and the heat dissipation capability from the lower surface 32a of the plate material 32 and the heat dissipation capability of the pillar-shaped bodies 35 are improved by the vortex flow. Additionally, the number of pillar-shaped bodies (pins) 35 is not increased from the state of FIG. 2A, so that the large fluid resistance is not generated with respect to the cooling fluid (refrigerant).

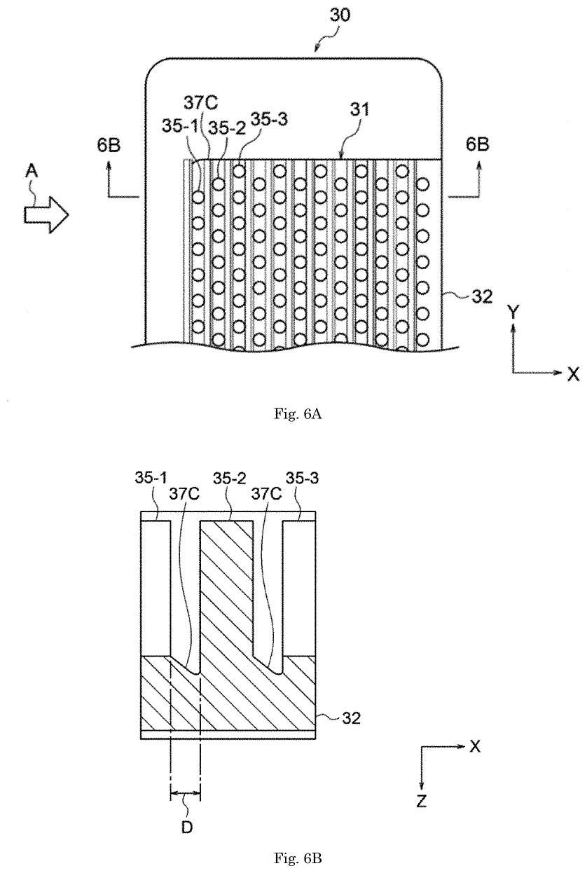

A fourth example embodiment of the present disclosure will be described with reference to FIGS. 6A and 6B. The fourth example embodiment is a modification of the first example embodiment. It is to be noted that description of configurations common to the first example embodiment will be omitted as appropriate. The same reference numerals are given to the same configurations as those of the first example embodiment. In the following description, differences from the first example embodiment will be mainly described.

FIG. 6A is a diagram corresponding to FIG. 3A, and FIG. 6B is a diagram corresponding to FIG. 3B. As seen from a comparison of FIG. 6B with FIG. 3B, although a cross-sectional shape of a groove 37C of the fourth example embodiment is a right triangle, the size of the groove 37C is different from that of the groove 37 of the first example embodiment. More specifically, the size D of the groove 37C of the fourth example embodiment in the X-axis direction is larger than that of the groove 37 of the first example embodiment, and the size (depth of groove) of the groove 37C in the Z-axis direction is also larger than that of the groove 37 of the first example embodiment. The cross-sectional shape (right triangle) of the groove 37C of the fourth example embodiment is a similar figure to the cross-sectional shape of the groove 37 of the first example embodiment.

As seen from FIG. 6B, the groove 37C is formed so as to connect (in contact with) the pillar-shaped bodies 35-1 in the X1 column and the pillar-shaped bodies 35-2 in the X2 column.

Also according to the present example embodiment, since the surface area of the lower surface 32a of the plate material 32 is increased by the grooves 37C, the heat dissipation capability of the heat dissipator 30 is improved. When the cooling fluid flowing from the direction of the arrow A to the lower surface 32a of the plate material 32 flows into the groove 37C, the vortex flow is generated by the groove 37C, and the heat dissipation capability from the lower surface 32a of the plate material 32 and the heat dissipation capability of the pillar-shaped bodies 35 are improved by the vortex flow. Since the groove 37C of the present example embodiment is a groove larger than the groove 37 of the first example embodiment, the vortex flow larger than that of the first example embodiment is generated.

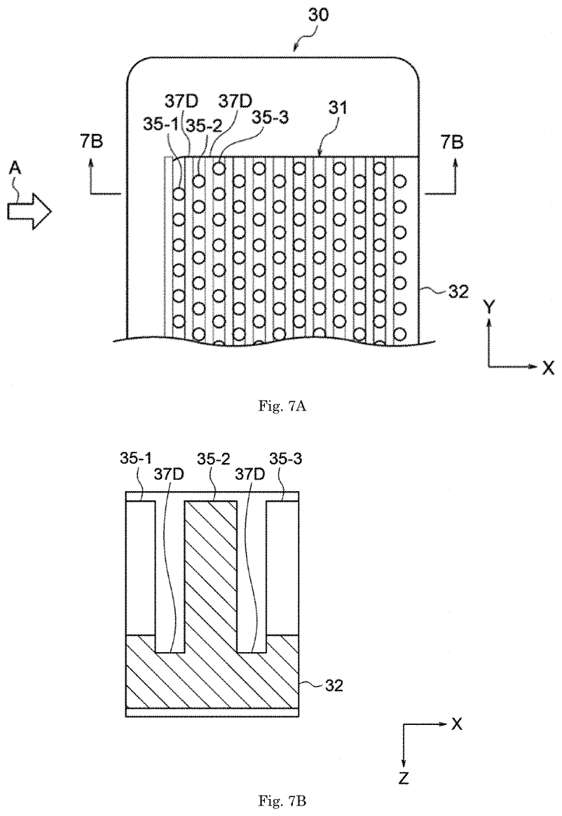

A fifth example embodiment of the present disclosure will be described with reference to FIGS. 7A and 7B. The fifth example embodiment is a modification of the fourth example embodiment. It is to be noted that description of configurations common to the fourth example embodiment will be omitted as appropriate. The same reference numerals are given to the same configurations as those of the fourth example embodiment. In the following description, differences from the fourth example embodiment will be mainly described.

FIG. 7A is a diagram corresponding to FIG. 6A, and FIG. 7B is a diagram corresponding to FIG. 6B. As seen from a comparison of FIG. 7B with FIG. 6B, a cross-sectional shape of a groove 37D of the fifth example embodiment is a rectangular shape. As seen from FIG. 7B, the groove 37D is formed so as to connect (in contact with) the pillar-shaped bodies 35-1 in the X1 column and the pillar-shaped bodies 35-2 in the X2 column.

Also according to the present example embodiment, since the surface area of the lower surface 32a of the plate material 32 is increased by the grooves 37D, the heat dissipation capability of the heat dissipator 30 is improved. When the cooling fluid flowing from the direction of the arrow A to the lower surface 32a of the plate material 32 flows into the groove 37D, the vortex flow is generated by the groove 37D, and the heat dissipation capability from the lower surface 32a of the plate material 32 and the heat dissipation capability of the pillar-shaped bodies 35 are improved by the vortex flow.

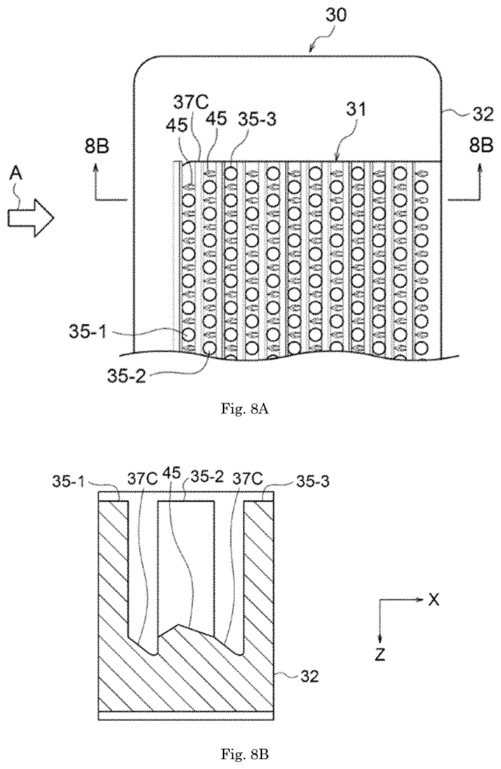

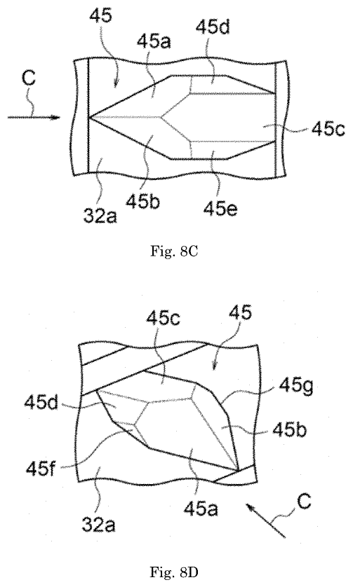

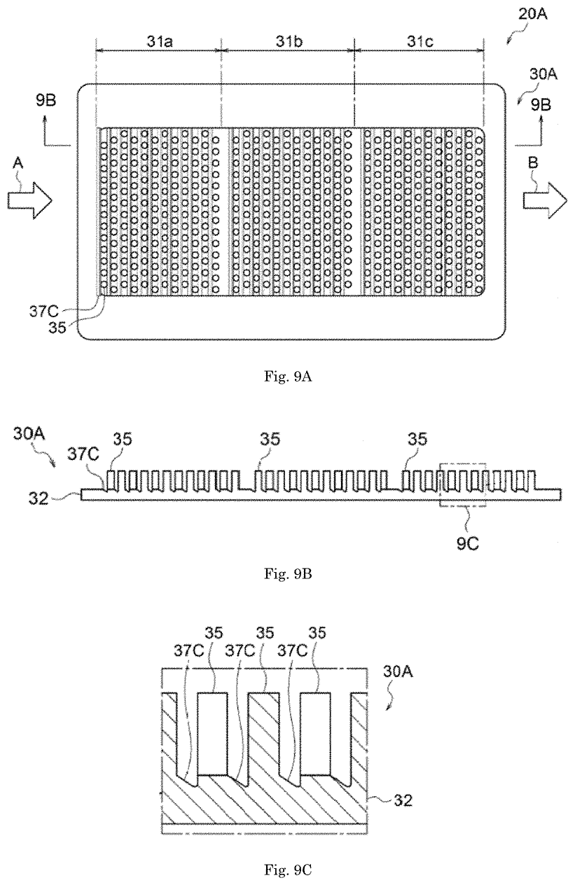

A sixth example embodiment of the present disclosure will be described with reference to FIGS. 8A to 8D. The sixth example embodiment is a modification of the fourth example embodiment. It is to be noted that description of configurations common to the fourth example embodiment will be omitted as appropriate. The same reference numerals are given to the same configurations as those of the fourth example embodiment. In the following description, differences from the fourth example embodiment will be mainly described.

FIG. 8A is a diagram corresponding to FIG. 6A, and FIG. 8B is a diagram corresponding to FIG. 6B. As seen from a comparison of FIG. 8A with FIG. 6A, according to the sixth example embodiment, small projections 45 are formed between the pillar-shaped bodies 35. FIG. 8C is a bottom view of each of the projections 45, and FIG. 8D is a perspective view of each of the projections 45. An arrow C indicates the cooling fluid. When the pillar-shaped body 35 is referred to as the first protrusion, the projection 45 may be referred to as a second protrusion. A height of each of the projections 45 is lower than that of the pillar-shaped body 35. The projection 45 may be referred to as a small protrusion. The projection 45 has a streamlined shape as a whole.

As seen from FIGS. 8C and 8D, the projection 45 has seven surfaces 45a, 45b, 45c, 45d, 45e, 45f, and 45g. The surface 45a and the surface 45b are pentagonal surfaces which are bilateral symmetrical, and are the surfaces with which the cooling fluid C first comes into contact. Each of the surface 45a and the surface 45b smoothly protrudes in the −Z side in the Z-axis direction from the lower surface 32a of the plate material 32. A tip portion of the projection 45 defined by the surface 45a and the surface 45b forms the wide-angle tip portion with an angle of a predetermined size. The tip portion described above reduces the fluid resistance to the cooling fluid C.

The surface 45c is a pentagonal surface positioned on the rear side (downstream side) of the surface 45a and the surface 45b, and is a surface smoothly extending toward the lower surface 32a. The surface 45d and the surface 45e are quadrangular surfaces positioned on the right and left of the surface 45c. Each of the surface 45d and the surface 45e is inclined at a predetermined angle with respect to the lower surface 32a. The surface 45f and the surface 45g are small triangular surfaces which are bilateral symmetrical, the surface 45f is formed between the surface 45a, the surface 45d, and the lower surface 32a, and the surface 45g is formed between the surface 45b, the surface 45e, and the lower surface 32a. The surface 45f and the surface 45g are the surfaces perpendicular to the lower surface 32a. When the cooling fluid C hits the projection 45, the vortex flow is generated.

According to the present example embodiment, since the surface area of the lower surface 32a of the plate material 32 is increased by the grooves 37C and the projections 45, the heat dissipation capability of the heat dissipator 30 is improved. When the cooling fluid C flowing from the direction of the arrow A to the lower surface 32a of the plate material 32 flows into the groove 37C, the vortex flow is generated by the groove 37C, and the heat dissipation capability from the lower surface 32a of the plate material 32 and the heat dissipation capability of the pillar-shaped bodies 35 are improved by the vortex flow. Additionally, since the vortex flow of the cooling fluid is generated by the projection 45, the heat dissipation capability from the lower surface 32a of the plate material 32 and the heat dissipation capability of the pillar-shaped bodies 35 are improved by the vortex flow.

A seventh example embodiment of the present disclosure will be described with reference to FIGS. 9A to 9C. A cooling device 20A of the seventh example embodiment includes a heat dissipator 30A having grooves similar to the grooves 37C described in the fourth example embodiment (FIGS. 6A and 6B). FIG. 9A is a bottom view of the heat dissipator 30A, FIG. 9B is a cross-sectional view of the heat dissipator 30A (cross-sectional view taken along line 9B-9B in FIG. 9A), and FIG. 9C is an enlarged view of a portion 9C in FIG. 9B. It is to be noted that description of configurations common to the fourth example embodiment will be omitted as appropriate. The same reference numerals are given to the same configurations as those of the fourth example embodiment. In the following description, differences from the fourth example embodiment will be mainly described.

As seen from FIG. 9A, the heat dissipator 30A includes three heat dissipation portions 31a, 31b, and 31c. The heat dissipation portions 31a, 31b, and 31c are arranged in series in the X-axis direction. Each of the heat dissipation portions 31a, 31b, and 31c has substantially the same configuration as the heat dissipation portion 31 illustrated in FIGS. 6A and 6B. The heat dissipator 30A of the present example embodiment is about 3 times the size of the heat dissipator 30 of the fourth example embodiment, and the number of pillar-shaped bodies 35 of the present example embodiment is about 3 times the number of pillar-shaped bodies 35 of the fourth example embodiment.

When the cooling fluid flows into the cooling device 20A from the direction of the arrow A, the cooling fluid is initially cooled by the most upstream heat dissipation portion 31a, subsequently cooled by the intermediate heat dissipation portion 31b, finally cooled by the most downstream heat dissipation portion 31c, and flows out of the cooling device 20A as indicated by the arrow B.

According to the present example embodiment, as compared with the fourth example embodiment, since the heat dissipator 30A has the three heat dissipation portions 31a to 31c (that is, the heat dissipation region is wide as a whole), the heat dissipation capability of the heat dissipator 30A is large, so that more heating elements are cooled. Since temperature of the cooling fluid increases as the cooling fluid travels downstream, arrangement of the heating elements provided on the upper surface 32b of the plate material 32 is preferably determined in consideration of a temperature increase of the cooling fluid.

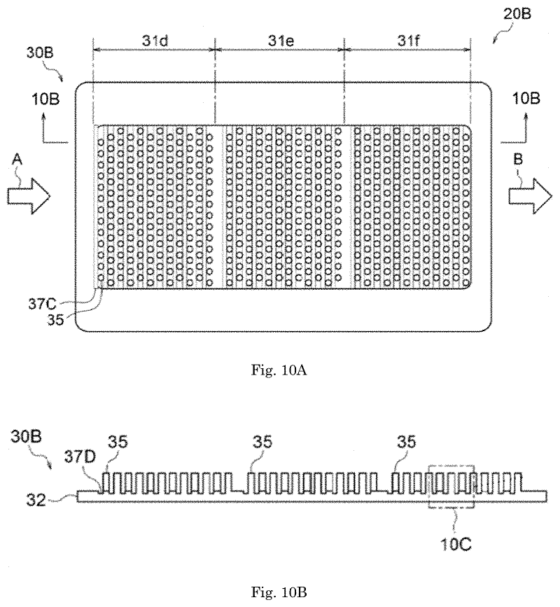

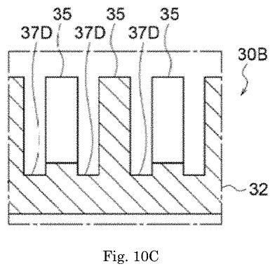

An eighth example embodiment of the present disclosure will be described with reference to FIGS. 10A to 10C. A cooling device 20B of the eighth example embodiment includes a heat dissipator 30B having grooves similar to the grooves 37D described in the fifth example embodiment (FIGS. 7A and 7B). FIG. 10A is a bottom view of the heat dissipator 30B, FIG. 10B is a cross-sectional view of the heat dissipator 30B (cross-sectional view taken along line 10B-10B in FIG. 10A), and FIG. 10C is an enlarged view of a portion 10C in FIG. 10B. It is to be noted that description of configurations common to the fifth example embodiment will be omitted as appropriate. The same reference numerals are given to the same configurations as those of the fifth example embodiment. In the following description, differences from the fifth example embodiment will be mainly described.

As seen from FIG. 10A, the heat dissipator 30B includes three heat dissipation portions 31d, 31e, and 31f. The heat dissipation portions 31d, 31e, and 31f are arranged in series in the X-axis direction. Each of the heat dissipation portions 31d, 31e, and 31f has substantially the same configuration as the heat dissipation portion 31 illustrated in FIGS. 7A and 7B. That, is, the heat dissipator 30B of the present example embodiment is about 3 times the size of the heat dissipator 30 of the fifth example embodiment, and the number of pillar-shaped bodies 35 of the present example embodiment is about 3 times the number of pillar-shaped bodies 35 of the fifth example embodiment.

When the cooling fluid flows into the cooling device 20B from the direction of the arrow A, the cooling fluid is initially cooled by the most upstream heat dissipation portion 31d, subsequently cooled by the intermediate heat dissipation portion 31e, finally cooled by the most downstream heat dissipation portion 31f, and flows out of the cooling device 20B as indicated by the arrow B.

According to the present example embodiment, as compared with the fifth example embodiment, since the heat dissipator 30B has the three heat dissipation portions 31d to 31f (that is, the heat dissipation region is wide as a whole), the heat dissipation capability of the heat dissipator 30B is large, so that more heating elements are cooled. Since the temperature of the cooling fluid increases as the cooling fluid travels downstream, the arrangement of the heating elements provided on the upper surface 32b of the plate material 32 is preferably determined in consideration of the temperature increase of the cooling fluid.

It is to be noted that the present disclosure is not limited to the present example embodiments described above. The present disclosure may adopt, for example, the following configurations.

(1)The cooling fluid may be other than water (such as, refrigerant EGW50/50).

(2)The heating element may be an object other than the electronic component.

(3)Additionally, each configuration and each example embodiment of the heat dissipator and the cooling device described above may be appropriately combined within a range not in conflict with each other.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A heat dissipator comprising:
a metal plate including a first surface through which fluid flows;
first protrusions on the first surface;
a recess in the first surface and between the first protrusions; and
a second surface which in contact with a heating element on an opposite side of the first surface.

2. The heat dissipator according to claim 1, wherein each of the first protrusions is a pillar-shaped body having a polygonal, circular, or elliptical cross section.

3. The heat dissipator according to claim 2, wherein a shape of the cross section of the pillar-shaped body is uniform or substantially uniform in a direction perpendicular to the first surface.

4. The heat dissipator according to claim 2, wherein an area of the cross section of the pillar-shaped body is varied in a direction perpendicular to the first surface.

5. The heat dissipator according to claim 1, wherein the recess includes at least one groove.

6. The heat dissipator according to claim 1, wherein the recess includes at least one of a groove extending in a direction in which the fluid flows and a groove extending in a direction intersecting with the direction in which the fluid flows.

7. The heat dissipator according to claim 1, wherein the recess includes grooves extending in parallel to each other.

8. The heat dissipator according to claim 1, wherein the recess includes grooves extending in non-parallel to each other.

9. The heat dissipator according to claim 5, wherein each of the at least one groove has a semicircular, semi-elliptical, or polygonal cross-sectional shape.

10. The heat dissipator according to claim 9, wherein the cross-sectional shape of each of the at least one groove is asymmetric.

11. The heat dissipator according to claim 9, wherein when the cross-sectional shape of each of the at least one groove is the polygon, a corner of the polygon is a smooth curved surface.

12. The heat dissipator according to claim 1, wherein the recess includes a plurality of grooves; and
a second protrusion is provided between adjacent grooves among the plurality of grooves.

13. The heat dissipator according to claim 12, wherein a height of the second protrusion is lower than a height of at least one of the first protrusions.

14. The heat dissipator according to claim 1, wherein the first protrusions are arranged perpendicular to a direction in which the fluid flows, and the recess is upstream of the first protrusions.

15. A cooling device comprising:
a heat dissipator according to claim 1; and
a housing that accommodates at least the first protrusions of the heat dissipator and allows the fluid to flow through a gap between the first protrusions; wherein
the housing includes an inlet and an outlet for the fluid.
